(19) United States
(12) Patent Application Publication
(10) Pub. No.: US 2017/0255516 A1
(43) Pub. Date: Sep. 7, 2017

(54) Field-Repair System and Method of Mask-Programmed Read-Only Memory

(71) Applicant: ChengDu HaiCun IP Technology LLC, ChengDu (CN)

(72) Inventor: Guobiao ZHANG, Corvallis, OR (US)

(73) Assignee: ChengDu HaiCun IP Technology LLC, ChengDu (CN)

(21) Appl. No.: 15/062,120

(22) Filed: Mar. 6, 2016

(51) Int. Cl. G06F 11/10; G06F 3/06; G11C 29/52

(52) U.S. Cl. CPC G06F 11/1072; G11C 29/52; G06F 3/0619; G06F 3/064; G06F 3/0679

(57) ABSTRACT

The present invention discloses field-repair system and method for a mask-programmed memory (mask-ROM). The mask-ROM data are encoded with an error-checking-and-correction (ECC) scheme. A self-checking circuit detects errors in read-out data without using any external data. When an error is detected, a communicating circuit fetches the good data from a remote server. As a result, most of the mask-ROM data can be checked and repaired in the field.

### CROSS-REFERENCE TO RELATED APPLICATIONS

This is a continuation-in-part of an application “Field-Repair System and Method for Large-Capacity Mask-Programmed Read-Only Memory”, application Ser. No. 14/732,887, filed Jun. 8, 2015, which is a continuation of an application “Field-Repair System and Method”, application Ser. No. 14/461,531, filed Aug. 18, 2014, which is a continuation of an application “Field-Repair System and Method”, application Ser. No. 13/597,220, filed Aug. 28, 2012, which claims benefit of a provisional application “Field-Repair System and Method for Pre-Recorded Three-Dimensional Read-Only Memory”, Application Ser. No. 61/529,923, filed Sep. 1, 2011.

### BACKGROUND

1. Technical Field of the Invention

The present invention relates to the field of the integrated circuit, more particularly to a mask-programmed read-only memory (mask-ROM).

2. Prior Arts

Mask-ROM is a read-only memory whose data are permanently recorded during manufacturing. With the advent of 3-D mask-ROM (3D-MPROM), the storage capacity of the mask-ROM greatly increases. U.S. Pat. No. 5,835,396 discloses a 3D-MPROM. It is a monolithic semiconductor memory. As illustrated in FIG. 1, a typical 3D-MPROM comprises a semiconductor substrate 0 and a 3-D stack 10 stacked above. The 3-D stack 10 comprises M (M≧2) vertically stacked memory levels (e.g. 10A, 10B). Each memory level (e.g. 10A) comprises a plurality of upper address lines (e.g. 2a), lower address lines (e.g. 1a) and memory cells (e.g. 5aa). Each memory cell stores n (n≧1) bits. Memory levels (e.g. 10A, 10B) are coupled to the substrate 0 through contact vias (e.g. 1av, 1av′). The substrate circuit OX in the substrate 0 comprises a peripheral circuit for the 3-D stack 10. Hereinafter, x M×n 3D-MPROM denotes a 3D-MPROM comprising M memory levels with n bits-per-cell (bpc).

3D-MPROM is a diode-based cross-point memory. Each memory cell (e.g. 5aa) typically comprises a diode 3d. The diode can be broadly interpreted as any device whose electrical resistance at the read voltage is lower than that when the applied voltage has a magnitude smaller than or polarity opposite to that of the read voltage. The memory level 10A further comprises a data-coding layer 6A, i.e. a blocking dielectric 3b. It blocks the current flow between the upper and lower address lines. Absence or existence of a data-opening 6ca in the blocking dielectric 3b indicates the state of a memory cell. Besides the blocking dielectric 3b, the data-coding layer 6A could also comprise a resistive layer (referring to U.S. patent application Ser. No. 12/785,621) or an extra-dopant layer (referring to U.S. Pat. No. 7,821,080).

Inevitably, a manufactured mask-ROM contains manufacturing defects. These manufacturing defects randomly occur and could cause errors to the mask-ROM. In a mask-ROM, an error occurs when the data read out from an address are different from the data intended to be recorded at the same address during manufacturing. Hereinafter, data refers to the logical data from the perspective of a user. In prior arts, a mask-ROM is fully factory-tested before shipping. Because all data are checked for errors and all errors are repaired at the factory before shipping, the shipped mask-ROM contains no errors. FIG. 2 illustrates a full factory-testing process. It is carried out in a tester and comprises the following steps: read the data at address A (step 61); check the data for errors, i.e. compare the read-out data with the good data (i.e. the data intended to be recorded at this address): if no error is found, increment the address A and check the next data (step 65); if an error is found (step 63), repair the error by fetching the good data from the tester (step 67) and writing the address A and the good data to a redundancy ROM (step 69); repeat the above steps for all data (step 70).

Because a conventional mask-ROM stores a limited amount of data, the full factory-testing, which takes a short time, is generally acceptable. However, as the storage capacity of the mask-ROM increases, the full factory-testing becomes difficult. For a TB-scale 3D-MPROM, it could take days to read out and check all data. Such a long test time makes the full factory-testing prohibitively expensive. Furthermore, during the course of its field use, the mask-ROM may suffer additional failures due to aging memory cells. Apparently, the full factory-testing cannot repair the aging errors.

### Objects and Advantages

It is a principle object of the present invention to shorten the factory-testing time and lower the factory-testing cost for a mask-ROM.

It is a further object of the present invention to repair the aging errors in the field.

In accordance with these and other objects of the present invention, field-repair system and method for a mask-ROM are disclosed.

### SUMMARY OF THE INVENTION

The present invention discloses field-repair system and method for a mask-ROM, more particularly for a 3D-MPROM. The field-repair system comprises a consumer processing apparatus (e.g. a playback device) and a mask-ROM card (i.e. a memory card containing at least a mask-ROM die). Different from prior arts, the mask-ROM in the present invention is only partially factory-tested before shipping. Because a large fraction of the mask-ROM data are not checked before shipping, the factory-testing time is considerable shortened and the factory-testing cost is significantly lowered.

Being partially factory-tested, the shipped mask-ROM may contain errors (i.e. the data read out from an address of the mask-ROM are different from the data intended to be recorded at the same address during manufacturing). With the help of a self-checking circuit, these errors may be detected in the field without knowledge of good data (i.e. data intended to be recorded). To be more specific, when data are recorded into the mask-ROM, the original data are encoded with an error-checking-and-correction (ECC) scheme. To be more specific, the original data are separated into blocks, with each block attached with a fixed number of check bits (or parity bits). The check bits are derived from the original data by a deterministic algorithm (e.g. Hamming code). The self-checking circuit can verify the correctness of the read-out data in each block by checking its bit field without using any external data. An exemplary self-checking circuit is an ECC circuit.

The present invention takes advantage of the fact that a communicating circuit is ubiquitous in the present-day consumer processing apparatus (e.g. a playback device which plays back the mask-ROM data). During the field use of the mask-ROM, when the self-checking circuit finds an error, the communicating circuit in the consumer processing apparatus fetches the good data to repair the error from a remote storage device, which stores a copy of good data. As a result, a faulty mask-ROM can be repaired in the field.

In prior arts (e.g. those disclosed in U.S. Patent Application Publication Nos. 2009/0008722 A1 and 2008/0313401 A1), the outdated data recorded in a mask-ROM can be remotely updated. These prior arts only address content updates, but do not address manufacturing errors. For them, the data recorded during manufacturing are assumed to be the data intended to be recorded. The error-checking method employed by these prior arts is a version-checking method, but not a self-checking method. To detect random errors occurred during manufacturing, these prior arts need to download a large amount of external data because every bit of read-out data needs to be compared with a corresponding bit of external data. Being done in the field, this download step takes even longer time than full factory-testing. In comparison, the method disclosed in the present invention needs to download a small amount of good data, i.e. it only downloads good data when an error is detected by the self-checking circuit.

### BRIEF DESCRIPTION OF THE DRAWINGS

FIG. 1 is a cross-sectional view of a 3D-MPROM;

FIG. 2 discloses a full factory-testing process for a mask-ROM (prior arts);

FIG. 3 discloses a preferred field-repair system and its communication with a remote server;

FIGS. 4A-4B illustrate two preferred processing apparatuses;

FIG. 5 is a flow chart showing a preferred testing method including partial factory-testing;

FIG. 6 discloses more details of the preferred field-repair system;

FIG. 7 is a flow chart showing a preferred field-repair method;

FIG. 8 is cross-sectional view of a preferred 3D-MPROM card.

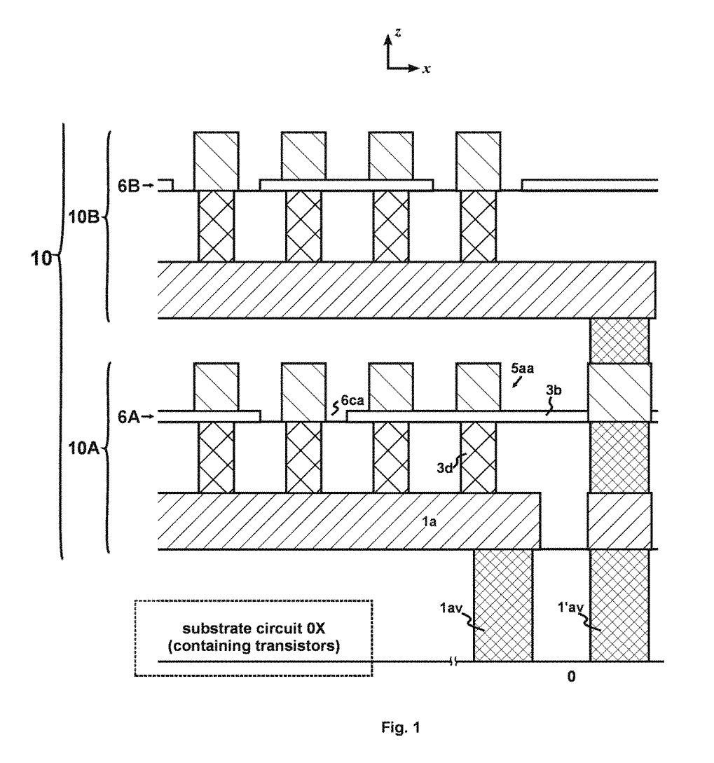

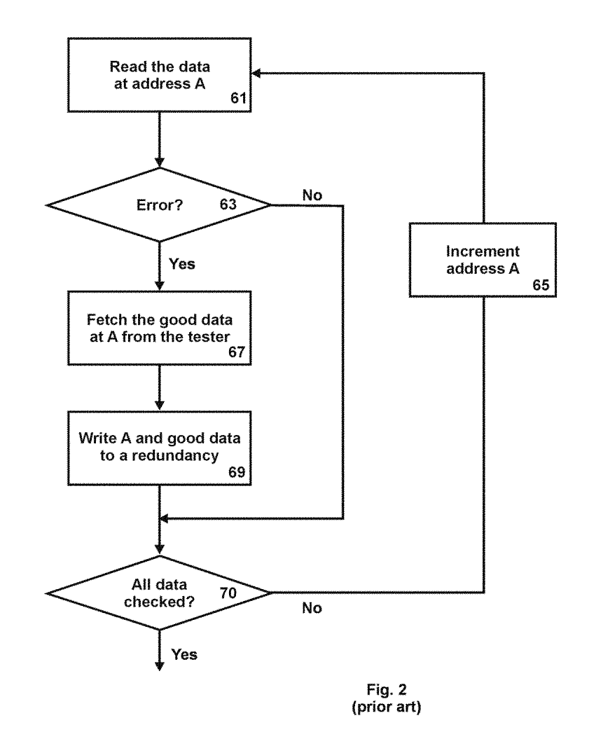

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention uses 3D-MPROM as an example to explain the concept of field-repair. The preferred embodiments disclosed herein can be extended to any large-capacity (GB and higher) mask-ROM. In the present invention, the primary data-recording means for a mask-ROM includes photo-lithography and imprint-lithography. The “mask” in the mask-ROM includes data-mask used in photo-lithography, as well as nano-imprint mold or nano-imprint template used in imprint-lithography.

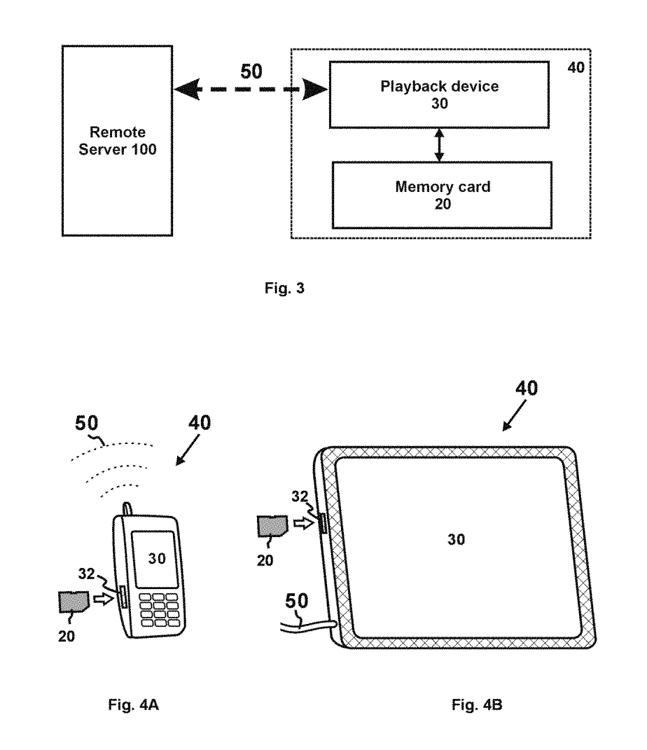

Referring now to FIG. 3, a field-repair system 40 and its communication channel 50 with a remoter server 100 are disclosed. The field-repair system 40 comprises a memory card 20 and a playback device 30. The memory card 20 could comprise a memory package or a memory module. It contains at least one 3D-MPROM die, more generally, at least a large-capacity mask-ROM die. The memory card 20 stores contents such as movies, video games, maps, music library, book library, and/or softwares. When data are recorded into the memory card 20, the original data are encoded with an error-checking-and-correction (ECC) scheme. To be more specific, the original data are separated into blocks, with each block attached with a fixed number of check bits (or parity bits). The check bits are derived from the original data by a deterministic algorithm (e.g. Hamming code).

The playback device 30, more generally, a processing apparatus, can read and process data from the memory card 20, e.g. playing a movie or video game, reading a map, listening to music, reading books, or running software. The playback device 30 generally communicates with a remote server 100 through a communication channel 50. The remote server 100, more generally, a remote storage device, stores a mass-content library, including a correct copy of the 3D-MPROM data. The communication channel 50 includes internet, wireless local area network (WLAN, e.g. WiFi) and cellular (e.g. 3G, 4G) signals.

FIG. 4A illustrates a preferred playback device 30—a cellular phone (or a pad device, or a tablet). It communicates with the remote server 100 via cellular signals 50 and/or WiFi signals 50. The cellular phone 30 further comprises a slot 32 for holding the memory card 20, which can be inserted into or removed from the cellular phone 30. During the use of the cellular phone 30, the data in the memory card 20 will be checked and repaired. FIG. 4B illustrates another preferred playback device 30—an internet TV (or, a computer). It communicates with the remote server 100 via internet signals (including wired and wireless internet signals) 50. The internet TV (or, computer) 30 further comprises a slot 32 for holding the memory card 20, which can be inserted into or removed from the internet TV (or, computer) 30. During the use of the internet TV (or, computer) 30, the data in the memory card 20 will be checked and repaired.

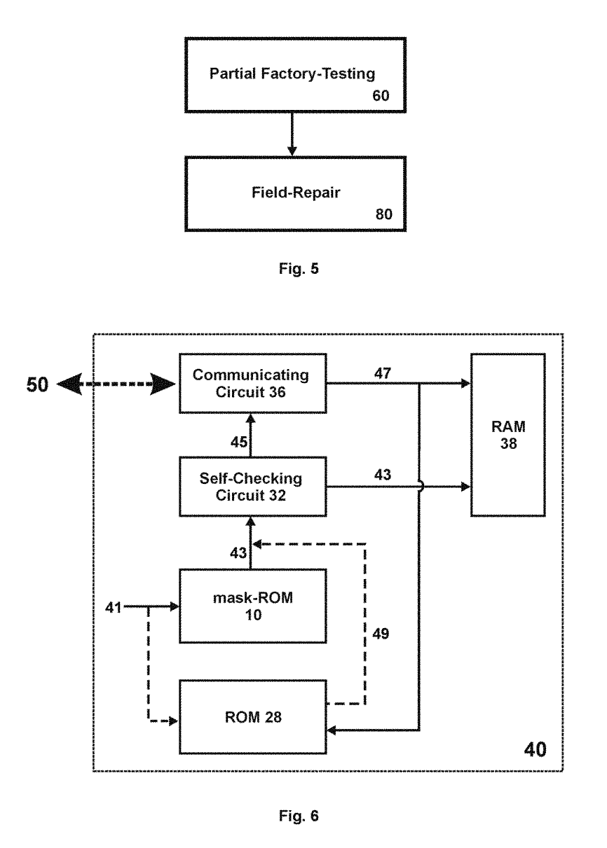

Unlike a conventional mask-ROM which is fully factory-tested and contains no bad data at shipping, the 3D-MPROM in the memory card 20 is only partially factory-tested (i.e. a large fraction of the 3D-MPROM data are not checked before shipping) and may contain errors at shipping. FIG. 5 discloses a preferred testing method for the memory card 20. It comprises a partial factory-testing step 60 and a field-repair step 80. The partial factory-testing step 60 just performs a basic test on the memory card 20 in factory, e.g. the integrity of its substrate circuit. At this step, most data in the memory card 20 are not checked, i.e. they are even not read out at all in factory! The partial factory-testing step 60 requires little factory-testing time and incurs little factory-testing cost. However, the memory card 20 would be found to contain errors if it were tested at shipping.

The field-repair step 80 is carried out in the field where the playback device 30 is being used. After the memory card 20 is inserted into the playback device 30, the 3D-MPROM data are checked and repaired in one of the following situations: 1) when the playback device 30 is idle (i.e. idle repair); 2) when the memory card 20 is in use, more particularly during its 1^{st} use (i.e. 1^{st}-use repair). In most cases, after it is repaired, the memory card 20 no longer needs to be repaired again. It can be directly used in other playback devices, e.g. the one that does not have internet access.

FIG. 6 discloses more details of the preferred field-repair system 40. It comprises a 3D-MPROM 10, a read-only memory (ROM) 28, a self-checking circuit 32, a random-access memory (RAM) 38, and a communicating circuit 36. Details of these components will be explained in the following paragraphs.

The 3D-MPROM 10 stores the content data. The 3D-MPROM data are preferably encoded with an error checking and correction (ECC) scheme. To be more specific, the original data are separated into blocks, with each block attached with a fixed number of check bits (or parity bits). The check bits are derived from the original data by a deterministic algorithm. The ECC-code examples include Reed-Solomon code, Golay code, BCH code, multi-dimensional parity code, Hamming code, and convolution code and others.

The ROM 28 functions as a redundancy memory for the 3D-MPROM 10. It stores the error addresses in the 3D-MPROM 10 and the associated good data. The ROM 28 could be a non-volatile memory that can be programmed at least once, e.g. a one-time-programmable memory (OTP), an EPROM memory, an EEPROM memory, or a flash memory. The redundancy ROM 28 is preferably located in a same memory card 20 as the 3D-MPROM 10. This way, the repaired memory card 20 can be used by other playback devices (including those without internet access). To read a repaired memory card 20, address 41 is first compared with those stored in the redundancy ROM 28. If there is a match, the data 49 from the ROM 28, instead of the data 43 from the 3D-MPROM 10, are read out. This is indicated by the dash lines of FIG. 6.

The self-checking circuit 32 can verify the correctness of the read-out data 43 in each block by checking its bit field without using any external data, i.e. without knowledge of good data. In a mask-ROM, an error occurs when the data read out from an address are different from the data intended to be recorded at the same address during manufacturing. Preferably, the self-checking circuit 32 is an ECC-circuit, i.e. it can also correct error(s). The self-checking circuit 32 can be located either in the memory card 20 or in the playback device 30.

The RAM 38 is part of the playback device 30 and it functions as a buffer (or, cache) for the 3D-MPROM data that are to be used by the playback device 30. Because fetching good data from the remote server 100 to the playback device 30 causes a considerable latency, this buffer RAM 38 is used in the playback device 30 to eliminate the effect of this latency on the user experience. During the field use of the 3D-MPROM, particularly during its 1^{st} use, a large amount of the RAM 38 is needed to buffer the 3D-MPROM data, because a virgin 3D-MPROM 10 may contain many errors.

The communicating circuit 36 is part of the playback device 30 and it provides communication between the playback device 30 and the remote server 100. Through the communication channel 50, the communicating circuit 36 fetches good data from the remote server 100. The communicating circuit 36 includes internet communication circuit, wireless local network (WLAN, e.g. WiFi) communication circuit and cellular communication circuit.

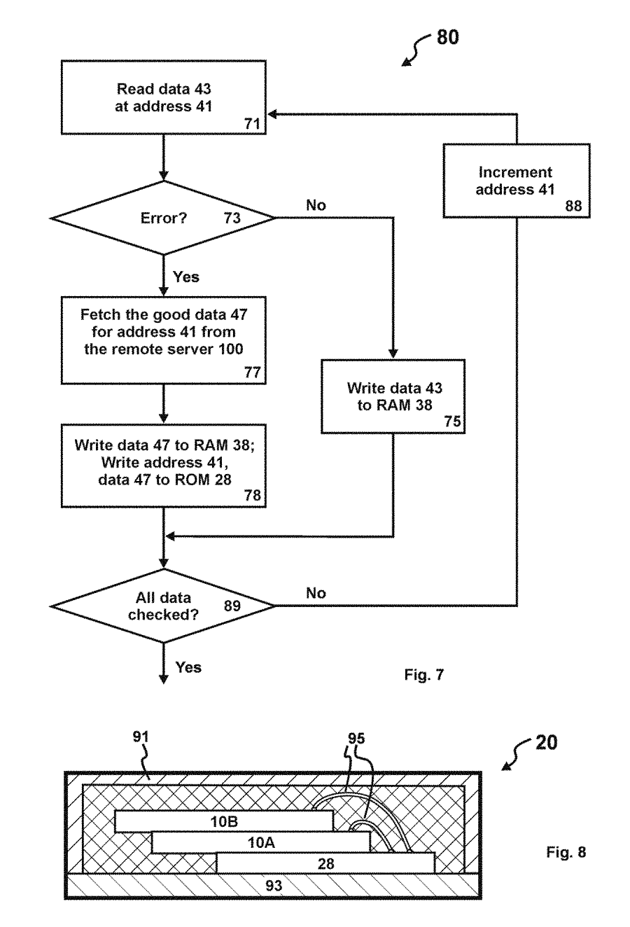

FIG. 7 is a flow chart showing a preferred field-repair method. It will be explained in combination of FIG. 6. First of all, the data 43 at address 41 are read out from the 3D-MPROM 10 (step 71). The self-checking circuit 32 checks the read-out data 43 without using any external data (step 73). If no error is found, the data 43 are written into the buffer RAM 38 (step 75). Otherwise, an error signal 45 is asserted and the good data 47 for the address 41 are fetched from the remote server 100 with the communicating circuit 50 (step 77). While the good data 47 are written into the buffer RAM 38, the good data 47 and the address 41 are also saved into the redundancy ROM 28 (step 78). In the present invention, the good data 47 and the address 41 are collectively referred to as redundancy information. These steps 71-78 are repeated for the incremented addresses 41 (step 88) until all data have been checked (step 89). Because errors are only a small proportion of the total data stored in a 3D-MPROM, the field-repair step 80 needs a small bandwidth from the communicating channel 50.

FIG. 8 discloses a preferred 3D-MPROM card 20. It is a multi-die package and comprises a plurality of vertically stacked 3D-MPROM dice 10A, 10B and a redundancy ROM die 28. These dice 10A, 10B, 28 are located in a package housing 91 and stacked on a package substrate (e.g. an interposer) 93. Bond wires 95 provide electrical connection among the dice 10A, 10B, 28. In this preferred embodiment, a single redundancy ROM die 28 stores the redundancy information for a plurality of 3D-MPROM dice (e.g. 10A, 10B).

Besides mask-ROM, field-repair can be applied to any pre-recorded content memory. A pre-recorded content memory is a semiconductor memory that stores at least a content before shipping. This pre-recorded content memory could be mask-ROM, one-time-programmable memory (OTP), EPROM, EEPROM and flash memory. During the course of its use in field, the pre-recorded content memory may suffer additional failures due to the aging of its memory cells. Accordingly, the present invention discloses a later-use repair. Although the pre-recorded content memory is repaired during the 1st use, the later-use repair continues to monitor and repair the content data during the later uses. To be more specific, a self-checking circuit checks the content data as they are read out from the pre-recorded content memory. If errors are found, the good data to correct these errors are fetched from a remote server with a communicating circuit. Here, the remote server stores at least a correct copy of the content being read. Overall, field-repair is carried out whenever data are read out from the pre-recorded content memory. It ensures that the data processed by the playback device 30 are always good data.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A field-repair system, comprising:
a mask-programmed read-only memory (mask-ROM), wherein the mask-ROM data are encoded with an error-checking-and-correction (ECC) scheme;
a self-checking circuit for detecting at least an error in said mask-ROM data without using any external data;
a communicating circuit for fetching the good data to correct said error from a remote storage device;
whereby a large fraction of the mask-ROM data are not checked before shipping.

2. The field-repair system according to claim 1, wherein said self-checking circuit is an ECC circuit.

3. The field-repair system according to claim 1, wherein said remote storage device is a remote server storing a copy of good data.

4. The field-repair system according to claim 1, wherein said communicating circuit is located in a processing apparatus.

5. The field-repair system according to claim 4, wherein said processing apparatus is a cellular phone, a pad device, a tablet, an internet TV, or a computer.

6. The field-repair system according to claim 1, wherein said communicating circuit includes an internet communication circuit, a wireless local area network (WLAN) communication circuit and a cellular communication circuit.

7. The field-repair system according to claim 1, further comprising a random-access memory (RAM) for buffering data from said mask-ROM.

8. The field-repair system according to claim 1, further comprising a read-only memory (ROM) for storing redundancy for said mask-ROM.

9. The field-repair system according to claim 8, wherein said mask-ROM and said ROM are located in a memory card.

10. The field-repair system according to claim 1, wherein said mask-ROM is a three-dimensional mask-ROM (3D-MPROM).

11. A field-repair method for a mask-programmed read-only memory (mask-ROM) whose data are encoded with an error-checking-and-correction (ECC) scheme, comprising the steps of:
1) reading data from said mask-ROM by a processing apparatus;
2) detecting at least an error in said mask-ROM by a self-checking circuit without using any external data;
3) fetching the good data to correct said error from a remote storage device by a communicating circuit;
whereby a large fraction of the mask-ROM data are not checked before shipping.

12. The field-repair method according to claim 11, wherein said self-checking circuit is an ECC circuit.

13. The field-repair method according to claim 11, wherein said remote storage device is a remote server storing a copy of good data.

14. The field-repair method according to claim 11, wherein said communicating circuit is located in said processing apparatus.

15. The field-repair method according to claim 11, wherein said processing apparatus is a cellular phone, a pad device, a tablet, an internet TV, or a computer.

16. The field-repair method according to claim 11, wherein said communicating circuit include an internet communication circuit, a wireless local area network (WLAN) communication circuit and a cellular communication circuit.

17. The field-repair method according to claim 11, further comprising the step of buffering the mask-ROM data in a random-access memory (RAM) after the step 1).

18. The field-repair method according to claim 11, further comprising the step of writing redundancy for said mask-ROM to a read-only memory (ROM) after the step 3).

19. The field-repair method according to claim 18, wherein said mask-ROM and said ROM are located in a memory card.

20. The field-repair system according to claim 11, wherein said mask-ROM is a three-dimensional mask-ROM (3D-MPROM).
